(19) United States
(12) Patent Application Publication
(10) Pub. No.: US 2005/0022086 A1
(43) Pub. Date: Jan. 27, 2005

(54) Method for generating tester controls

(76) Inventors: Anton Kotz, Marktoffingen (DE); Uwe Bruckdorfer, Riesbuerg (DE); Matthias Haschka, Kirchheim (DE); Kurt Feldmeyer, Riesbuerg (DE); Peter Klein, Hainsfarth (DE)

Correspondence Address: SCHOLL PATENT AGENCY, INC.;DR. MATTHIAS SCHOLL, 800 MAIN ST, #308, HOLDEN, MA, 01520, US

(21) Appl. No.: 10/823,498

(22) Filed: Apr. 13, 2004

(30) Foreign Application Priority Data
Apr. 15, 2003 (DE) DE 103 17 431.1

(51) Int. Cl. G01R 31/28; G06F 11/00

(52) U.S. Cl. 714/742

(57) ABSTRACT

The invention refers to a method which generates an IC tester control consisting of numerous test instructions for a plurality of specific test environments, which can generate and measure analog and digital signals for an IC, in particular a mixed-signal IC. The method obtains data and control instructions from multidimensional test matrices independent of the test environment, such as matrix-like databases or libraries. The data and control instructions independent of the test environment are converted by means of a code generator into a syntax which is dependent on the test environment and which can be integrated into a general syntax dependent on the test environment, so that the syntax dependent on the test environment and the general syntax dependent on the test environment together form a complete control, comprising analog and digital signals, for one of the specific test environments.

### CROSS-REFERENCE TO RELATED APPLICATIONS

Pursuant to 35 U.S.C. §119 and the Paris Convention Treaty, this application claims the benefit of German Patent Application No. DE 103 17 431.1, filed on Apr. 15, 2003, and incorporated by reference herein.

### STATEMENT REGARDING FEDERALLY SPONSORED RESEARCH AND DEVELOPMENT

Not Applicable

### BACKGROUND OF THE INVENTION

The invention relates to a method by means of which a plurality of data and control instructions independent of the test environment are transformed into a control method which is dependent on the test environment and is capable of running in a certain test environment for testing ICs which combine analog and digital circuits. It furthermore relates to a control corresponding to the method.

Electronic circuits which are present as integrated circuits, also referred to as ICs, must be tested prior to installation in housings or prior to installation on circuit boards, in order to offer appropriate safety and low probability of failure. Particularly in the case of applications of ICs which have to offer a high degree of reliability, such as, for example, in automotive construction, in telecommunication or in the aerospace industry, it is frequently necessary to ensure virtually complete function test covering. Function test covering is checking whether the IC to be tested actually offers all functions envisaged and in all cases also has the intended response. In their housing, these ICs frequently combine circuits which may process both analog signals and digital signals.

Such ICs are tested using test environments which are referred to for short as testers with load boards and are available from many, different suppliers. Some testers are designed so that they test only analog circuits, while other in turn can test exclusively digital circuits, and a further type of tester offers analog and digital test resources. The testers T6673, T6683 from the supplier Advantest® Europe GmbH, which has an agency in 81929 Munich, Germany, the tester Octet™ from the supplier Credence Systems Corporation from Fremont, Calif. 94539, USA, the tester SZ 3650 and Falcon from the suppliers Credence-SZ GmbH, with an agency in Wasserburger Str. 44, D 83123 Amerang, Germany, and the supplier Teradyne Inc., from Boston, Mass. 02118-2238, USA, which offers the tester Integra Flex, may be mentioned by way of example. Each tester is to be programmed for the IC to be tested in a language or syntax which is typical for it and which depends on which manufacturer constructs the tester. The programming of a tester can take up to two man-years, depending on the extent of the function test coverage intended. The programming can be carried out only by those programmers who are not only capable of programming the testers in their respective own syntax but are also able to develop a good understanding regarding which tests are to be carried out and how they are to be carried out, at which operating points and under which test environment conditions the IC to be tested is most likely to exhibit undesired phenomena and how the functionality of the tester can be applied to the desired function test coverage.

In comparison, the product innovation cycles have constantly decreased in recent years so that in some cases, primarily in the telecommunications sector, the phase of an innovation cycle itself is complete within two years. Consequently, the control is available for a certain tester only when the innovation cycle is already complete. Contrary to the expectations of the users, therefore, ICs which actually should be tested but owing to lack of time can no longer be tested are included in a product. A further complicating factor is that test programs designed are capable of running only on one tester. If it is intended to change from tester to another tester for capacity reasons relating to the tester, or even from one tester family to another tester family, the new tester generally has to be completely redesigned for the test requirements. For the design, it is then necessary to engage a developer who is exactly familiar with the new tester, including its syntax, and it is therefore necessary to rely on a very limited number of specialists, who are difficult to find.

In order to counteract some of the difficulties described, the patent literature discloses a variety of approaches. EP 0 056 895 B1 proposes programming a central processor means with a universal language, such as ATLAS, and transmitting the instructions to be compiled, via IEEE 488 buses, to various dependent processors which transmit the respective test signal to the unit under test (UUT or DUT), i.e. the IC, via a switching matrix. In summary, it may be stated that EP 0 056 895 B1 of 1981 describes a procedure in which, on a central processing unit which is to be programmed in a high-level language, the test instructions are processed for a specific tester module network whose individual modules are all tailored to a DUT. Generally, a tester is described which manages with a plurality of processors which perform various tasks in order to generate and to measure voltages, currents or frequencies.

U.S. Pat. No. 5,206,582 discloses that attempts were constantly being made even as long as more than 10 years ago to reduce the test effort. At this time, individual transistors were tested, which had not yet been subjected to a test environment in isolated form on a common wafer. The test objectives were based on the production process for individual transistors, i.e. the position of the transistors in the wafer layout had to be recorded in an input sheet, the individual dice were then specified, etc. On the basis of the electronic components to be tested, such as transistors and diodes, threshold value tests of analogous quantities, such as, for example, the current, are carried out. Matrices serve for spatially determining the exact location on a wafer where the tester has to be applied. A similar tester system is described in EP 0135 864 A2, which can carry out tests of storage modules with AC and DC tests and AC test patterns. An interactive input element records the test data, and the input test data are translated for their target hardware by a multiplicity of universal test translators, each test translator being designed for the associated tester. The system described is in turn therefore a tester which consists of a multiprocessor system whose individual processors each process individual test sequences.

With the aim of relieving the individual testers, in more recent developments, as reported, for example, in U.S. Pat. No. 5,682,392 or in U.S. Pat. No. 6,202,183, the ICs which contain both analog and digital circuits (mixed signal ICs) are themselves to be equipped with test functionalities which are addressable by a tester via a TAP or ATAP (test access port or analog test access port) and output the result of the test via the TAP. The proposed solution is appropriate in the case of extremely complex ICs in which the additional silicon surface which is consumed by the integration of the test circuits is unimportant. In the case of ICs which have only moderate complexity, on the other hand, it is important that the entire desired functionality of the IC is covered with as little silicon surface as possible.

Another approach is presented in the two documents U.S. Pat. No. 6,353,904 and DE 195 23 036 A1. In both documents, for the reusability of program sequences, sequences prepared on testers can be stored in libraries or forms in order subsequently to integrate the individual blocks again in a new test program with appropriate adaptations. The approach can be used when the electronic circuit arrangement of the tester for the new IC remains substantially identical to the earlier tester configurations. Subdivision below the level of a test block as the smallest unit is not possible. The compilation of libraries for high-level language programming, which nowadays is typical for the programming of testers, can be carried out in each case for an individual tester. If the test programmer has a plurality of testers, if possible from different tester manufacturers, the approach of the two documents is not promising.

To simplify the transition from an IC design to a test program design, U.S. Pat. No. 6,182,258 B1 recommends testing the operability of the modules and chip parts, which are designed in an HDL language, by means of an initiator for a simulator which is written in a language such as C or C++. By means of the simulation in the design phase, errors present in the design of the IC can be avoided. To enable the errors to be found, random test patterns are worked through. It is not necessary first to produce ICs in order to note later on in a test phase that the design has decisive logic errors.

U.S. Pat. No. 6,205,407 proposes a method by means of which the computational time and the amount of data produced by a test program can be reduced. Instead of allowing the finished test program, which is run through according to its function sequence or according to its curve shape, according to its translation parts and its tester hardware, to run in a multiple process several times through the parser, the patterns and the sequences for the tests are extracted from the test program and sent directly to the translator, which transmits the data to the tester hardware. A tester hardware description input via a GUI interface can be stored in a file and later on called up again and integrated for a new test program. The developers of the method described have recognized that it is advantageous to create finished test hardware descriptions once and for all and to be able to reuse them later on again and again. However, in spite of this simplification, the capacity of the translator is utilized to such an extent that all possible tricks have to be used to enable the test procedure to be carried out in acceptable times.

DE 101 01 067 A1 envisages the need for universal programming routines for testers. It is also explained that it would be a problem if the universal programming routines, which are written, for example, in C or JAVA, also contain elements which are important for the respective tester hardware. As a solution, the universal tester routine should therefore contain only general components, and the routines which are required specifically for the tester should be called up by the universal program, which is integrated in a key routine exactly in the manner of the specific program. The function test may comprise DC and RF tests. It is therefore possible for the test program to be created by a programmer who need not be familiar with all fine points of the tester hardware. However, he should be familiar with the access points for the individual test routines of the tester hardware. In the end result, DE 101 01 067 A1 describes a method which is referred to in the computer world as a sandbox system or nested routines. The fact that a programmer no longer need be familiar with all fine points of the tester hardware but, in spite of the universal programming language, such as C, an overall routine or overall program results which forms a narrow-mesh network between specific commands and standardized universal commands is moreover disadvantageous. Although this procedure enables even less qualified programmers to write test programs, the result of their work can be used only on one tester hardware and must in each case be transferred afresh to another hardware.

A further approach for creating test programs which are as universal as possible is the design of a programming language, such as STIL (Standard Test Interface Language), described in the standard IEEE 1450.0 to IEEE 1450.6, which has been designed for digital ICs. It standardizes the definitions with which digital ICs can be tested. However, many ICs now no longer have only digital circuit groups but also have an analog region.

### SUMMARY OF THE INVENTION

It is therefore desirable to recognize a method with the aid of which it is possible to test ICs which combine both analog and digital circuit groups (true mixed signal ICs, such as, for example, mobile telephone ICs or SOC-ICs (system on chip ICs)). Mixed signal ICs have their very own requirements. Thus, in the case of such ICs, it is necessary to test gains, frequency responses, phase positions, wave shapes, harmonics and transit-time behavior. As is easily understandable from the large number of test objectives, the objective in question is one which many renowned tester and software manufacturers have been afraid to tackle to date because the objective was considered to be not capable of being solved.

Furthermore, the control for the tester should be so universal that persons who have test experience and programming experience can design the tester configuration. Here, the specific programming language for a tester should not be replaced by another specific, newly created programming language, but a method should be strived for by means of which universalists can design, for many different testers from different tester suppliers, tester controls which, depending on resource requirements and utilization of the testers, can be transferred from one tester to another tester without many man-months or even man-years having to be applied for this purpose.

These and other advantages are offered at least partly by a method as claimed in claim 1, claim 7 and claim 14. Suitable embodiments are to be found in the dependent claims. The method can be applied to universal computers as claimed in claim 22 and can be transferred from one computer to another by means of a data medium or electronically as claimed in claim 21.

The method generates an IC tester control consisting of numerous test instructions for a plurality of specific test environments, which can generate and measure analog and digital signals for an IC, in particular a mixed-signal IC, wherein
the method obtains data and control instructions from multidimensional test matrices independent of the test environment, such as matrix-like databases or libraries,
the data and control instructions independent of the test environment are converted by means of a code generator into a syntax which is dependent on the test environment and which can be integrated into a general syntax dependent on the test environment, so that the syntax dependent on the test environment and the general syntax dependent on the test environment together form a complete control, comprising analog and digital signals, for one of the specific test environments.

A further method generates an IC tester control, consisting of numerous test instructions, for a plurality of specific test environments, which can generate and measure analog and digital signals for an IC, in particular a mixed-signal IC, wherein
the individual specific test environments differ from one another in their structure and/or their syntax, the method obtains data and control instructions from multidimensional test matrices independent of the test environment, such as matrix-like databases or libraries,
the data and control instructions independent of the tester environment are converted by means of a code generator into a syntax which is dependent on the test environment and which can be integrated into a general syntax dependent on the test environment, so that the syntax dependent on the test environment and the general syntax dependent on the test environment together form a complete control, comprising analog and digital signals, for one of the specific test environments.

A still further method generates an IC tester control, consisting of numerous test instructions, for a plurality of specific test environments, which can generate and measure analog and digital signals for an IC, in particular a mixed-signal IC, wherein
the method obtains data and control instructions from multidimensional test matrices independent of the test environment, such as matrix-like databases or libraries,
the data and control instructions independent of the test environment are converted by means of a code generator into a syntax which is dependent on the test environment and which can be integrated into a general syntax dependent on the test environment, so that the syntax dependent on the test environment and the general syntax dependent on the test environment together form a complete control, comprising analog and digital signals, for one of the specific test environments, and
test methods which allow both digital and analog signals of the control of the test environment to occur synchronously can be listed in the multidimensional test matrices.

The data medium can be processed by a microprocessor-controlled computer on which the method according to the invention is physically incorporated.

The microprocessor-controlled computer has a central operating system which is electrically connected to at least one test environment on which the method according to the invention runs.

The method creates an IC tester control which can be applied to any tester families and testers such as, for example, the M3650 from Credence-SZ Testsystemen GmbH or the T3340 from Advantest® Europe GmbH. The tester families differ in their structure, their composition, their operability, their individual syntax, their capabilities, which tests can be carried out at all, etc. A matrix-like representation or arrangement of the tester control, which is not designed specifically for one tester but compiles data independent of the test environment and relating to the IC to be tested, which may be an analog, a digital or a mixed-signal IC, is chosen as a starting point. The data can be filed or stored and are available for further processing by the test control designer, as a library or database or at a certain point in a computer. The data can be read into the computer later on again and can be processed. The test matrices comprise numerous data, such as, for example, the exact pin position of the IC to be tested, the designation of the IC, the designation of the pins, the definition of the supply voltages, data on limits of measured values, measures for bringing the circuit of the IC into a state such that it can be tested, etc. The data are collected together in the test matrices, which are multidimensional. Per IC, there is a test matrix which gives a complete description of the tests to be performed in a universal manner comprehensible to a machine. Depending on the scope of the desired data, a matrix may have six, eight, ten or even more dimensions. Parallel to the test matrix, a notation in a general tester language, abbreviated to GTL, is also possible. The user can either work on the matrix representation or can work in an editor in the GTL version. The respective test matrix is available to a code generator. The code generator transforms the data, which are independent of the test environment and are also present as syntax independent of the test environment, into a syntax for a very specific, selected and defined test hardware. After successful processing, the code generator delivers either a syntax which is dependent on the test environment and is present in a high-level language specific to the respective tester, or a completely compiled syntax which is capable of running on the respective tester without any further transformation step, i.e. in a low-level, machine-readable language. The syntax is reduced to a minimum. All parts which relate to the general control of the tester, such as, for example, screen controls, self-tests of the tester, initialization procedures of the tester and calibrations of the tester, are present in a general syntax which is not converted by the code generator. A code generator part defined as a linker employs the general syntax to link the converted syntax dependent on the test environment to the other, existing syntax and thus to produce an executable sequencer and tester control therefrom.

The method has the advantages that the data of the tester control, which consist of numerous test instructions, are present centrally. The test designer, a universalist from the area of electrical engineering, electronics or technical information technology, both with know-how in the area of the IC test and with know-how concerning the possibilities of what can be tested, can realize all data in matrix form. The data can be repeatedly called up, filed, stored and processed. If, in the course of time, it is found that a part of the test cannot yet check all desired properties of an IC or excludes all possibilities of failure, further test methods and individual tests can easily be integrated into the matrix form. If, after a successful test of an IC type, a similar IC is to be introduced into the test environment at a later time for another test, the earlier matrix can be used again. The test designer once again checks the desired test and if necessary makes small adaptations or extends the scope of the test with new knowledge gained in the meantime. By means of a simple choice as to the tester hardware on which the IC test is to be subsequently performed, the code generator converts the IC tester control from the compilation of the actual tests, independent of the test environment, into the syntax and command sequence specific for the corresponding tester. If it is subsequently found that another tester is more suitable or that it is available instead of the planned tester, all that is necessary is to choose the new test environment for the code generator, and no further steps are necessary apart from starting the conversion procedure and the conversion phase and applying the result to the corresponding test environment.

The test environment itself is composed of the tester hardware, which originates from the supplier of the tester hardware, and load boards specially adapted for the individual test. During the conversion phase, the code generator can access libraries which contain, inter alia, information on the load boards and the test environment. Because one tester offers only a certain number of voltage sources but a larger number of current sources, and another tester also offers frequency generators instead of the many current sources, a library must contain information regarding the maximum available resources with respect to current and voltage sources or other sources and measuring transducers for each test environment. Moreover, the conversions of the signal from, for example, a voltage signal to a current signal must be stored in a library. The wiring of the load board and the layout of the load board influence the impedance, the frequency behavior and the signal velocity of the channel which is chosen for a signal. The information regarding a load board is available in a library to the code generator.

In some ICs, in particular ICs provided with the code MIL, it is important that testing is also effected in temperature ranges of 150° C., if not even up to 175° C. Heated ICs require a corresponding cooling phase before they can be tested again at normal ambient temperatures. In order to shorten the test times, it is important to note such details. The code generator should therefore also access libraries in which sequences of test methods can be monitored and, if desired, can be optimized and shortened. It, may sometimes be advantageous to divide the individual optimizations into different libraries; in other cases, it may be advantageous to combine code generator optimizations, test environment resources, sequences of test methods and other information in one library. In general, there must be one library or a plurality of libraries which can be understood by the code generator and have information on one or more of the following aspects: the test environment, the syntax dependent on the test environment, the test environment resources, the sequence of test methods, the standard functions of the test environment, the load board structure, the load board-dependent standard functions and the code generator optimization. Standard functions are defined as the commands, controls and instructions which in turn conceal a number of individual controls together, such as, for example, wake-up function, temperature test or input test. As an alternative, it is also occasionally advisable to provide a library interface which makes the libraries available to a third party, such as, for example, a user of the method.

The multidimensional test matrix combines numerous pieces of information in different dimensions. In a first dimension, which may optionally be arranged horizontally or vertically, the pins of an IC are listed with respect to their number and with respect to their arrangement. In a superposed dimension, which lies on a plane other than the plane which specifies the information on the number and the arrangement of the pins of an IC relative to one another, the significance of the pins, their respective name and the signal flow direction per pin are specified. In other dimensions of the test matrix, test instructions, general test instruction definitions and test patterns are specified. If, for example, testing is to be effected at different temperatures, the test boundary conditions must be specified in a further dimension. Furthermore, the maximum and minimum supply current may be a test boundary condition. The speed with which the IC responds and outputs the desired measured value, or the actual supply current of the IC, can be specified as a condition for quality sorting in a dimension, which is sorted by means of switching values into different quality classes which correspond to the specifications according to CECC 90000 and CECC 90200 (binning). In order to specific switching hystereses, levels and switching conditions, switching values are to be specified in one or more dimensions. For a better understanding of the scopes of the tests, of the importance of the test boundary conditions and of the intentions or purpose of the specified tests, information about the functional description of the tests are provided in a dimension of the matrix.

Depending on the IC types for which it is to be used, the code generator requires differing generators and modules. If all modules and generators are required, the generator comprises a DC test generator, an AC test generator, a digital test generator, a load board generator and a test control verifier. The generator passes through the matrices several times. In a first stage, the matrices are prepared in a version processible for the code generator. The data and control instructions which are processible by one of the test generators are extracted from this version. The data and control instructions which are processible by another test generator are then extracted. As a further step, a check is carried out as to whether all test rules are processible and whether the resources regarding the test environment, the tester and the load board are to be implemented. Finally, optimization is effected according to one criterion or a plurality of criteria, and advantageous criteria are transit-time optimizations, advantageous test sequence conditions and advantageous resource planning.

The digital test generator creates program segments by reading in the vector table of the test data and setting the level of the digital pins with respect to the drivers, the comparators and the loads. Further tasks performed by the digital test generator are the determination of the start and stop address of the vector table, the specification of expected responses during the test evaluation and the setting up of curve shapes and time conditions. For the creation of the vector table, it is helpful to take account of status tables of the input pins and of the output pins and to specify the description of the input and output statuses as a function of time. The curved shapes must be specified for this purpose.

The DC test generator creates program segments based on matrix specifications with the test data and the control instructions. It uses the corresponding parts or dimensions of the matrix specifications in order to specify the starting conditions necessary for the tests. The suitable stimuli, such as, for example, which current or which voltage is desired, with respect to magnitude, sign, accuracy and resolution, are then produced in order to apply them to the selected pins of the IC. Which measurement corresponds to the stimuli and where the measured result is to be filed, i.e. the nature of result handling, are then determined. If the test sequence is specified for one stimulus, the settings must be reset in order thereafter, in a further step, to carry out the same translation or conversion steps for the next control instruction from a matrix.

The AC test generator has the task of extracting the stimuli with respect to the suitable contact on the IC, the desired curve shape, the frequency of the signal of the stimulus and the accuracy from the test description, independent of the test environment, of tests having changing signal sequences. Similar information must be specified in the matrices in respect of the curve shape, the frequency, the amplitude and the pin on the IC of the signal to be measured. After the stimulus has been specified in terms of its type, it is necessary to ensure in the program segment that the respective stimuli have been synchronously applied. By means of DSP calculations, i.e. digital signal processor calculations, the individual parameters, such as, for example, the gain, the signal/noise ratio, etc., are to be determined. The measured result is to be evaluated and optionally, in the case of a quality class sorting procedure (binning), to be sorted into its corresponding class. To be able to set the individual stimuli, it is necessary to bring the setting of the tester, of the load board or of the total test environment into a neutral starting state, a so-called reset state, between each stimulus or each group of stimuli, i.e. the stimuli which have be simultaneously applied to different IC pins, before further stimuli are to be applied.

The load board generator has the task of establishing the connection between the head of the tester, the component which permits electrical access to the tester, and the IC. The library corresponding to the load board generator has gathered together the data of all load boards which are already present. One task of the load board generator is therefore to check whether the required boards already exist. Here, a check is simultaneously carried out to determine whether another, existing board meets the requirements for all load boards. If the fund of existing load boards is not sufficient, the load board generator determines whether an existing load board can be adapted for the new task with little effort. It is particularly advantageous if the load board generator can operate with output formats of standard layout programs and standard electronic simulation programs, such as, for example, Protel® from Altium, Orcad® from Credence Design System, Eagle® from Cadsoft or P-SPICE®. If no suitable load board from the existing fund is available or can be adapted, corresponding part lists or network plan lists for the interfaces to the IC and to the head of the tester are drawn up, which indicate the load board circuit to be processed as a box still to be defined, so that the tester and developer know that a load board is to be designed as a link between the head of the tester and the pin of the IC.

The method comprises test methods which can be listed as individual test methods in the multidimensional test matrices. The test methods which have been developed specifically for mixed-signal ICs, allow both digital and analog signals to occur synchronously at the control of the test environment. The full functionality of a mixed-signal IC can also actually be tested by the time synchronicity, i.e. a corresponding analog signal is present at an analog pin of the IC and at exactly the same time a corresponding digital signal is present at a digital pin of the IC.

However, according to another aspect of the invention, the method offers the possibility of reading in the signals, which are analog and/or digital signals, from the test environment, preferably with a time lag after superposition of the signals of the control, in order to be evaluated via mixed-signal test methods, such as, for example, a method which measures the individual gain or plurality of gains, which measures the voltage conditions, which measures the frequency response of the signals, which measures the phase positions of the signals relative to one another, which measures the wave shapes of the signals or which measures the harmonics, especially by means of Fourier analysis, and/or which measures the transit-time behavior. Thus, not only can mixed signals be applied to the IC to be tested but the responses of the IC to be tested can also be analyzed by mixed-signal methods.

The method can be incorporated in the form of software and stored on data media. The method is capable of running on computers having one more processors under all conventional operating systems, such as Linux, Unix or Windows.

### BRIEF DESCRIPTION OF THE DRAWINGS

The invention can be even better understood with reference to the following figures,

FIG. 1 showing the method as a first block diagram,

FIG. 2 showing the architectural integration of the generated syntax into the general syntax,

FIG. 3 showing a test matrix for an analog-digital test,

FIG. 4 showing a further test matrix for an analog test,

FIG. 5 showing a folded test matrix whose first row is partly unfolded,

FIG. 6 showing the method in a further embodiment,

FIG. 7 showing a schematic diagram of a mixed-signal test arrangement with test object.

### DETAILED DESCRIPTION OF THE PREFERRED EMBODIMENTS

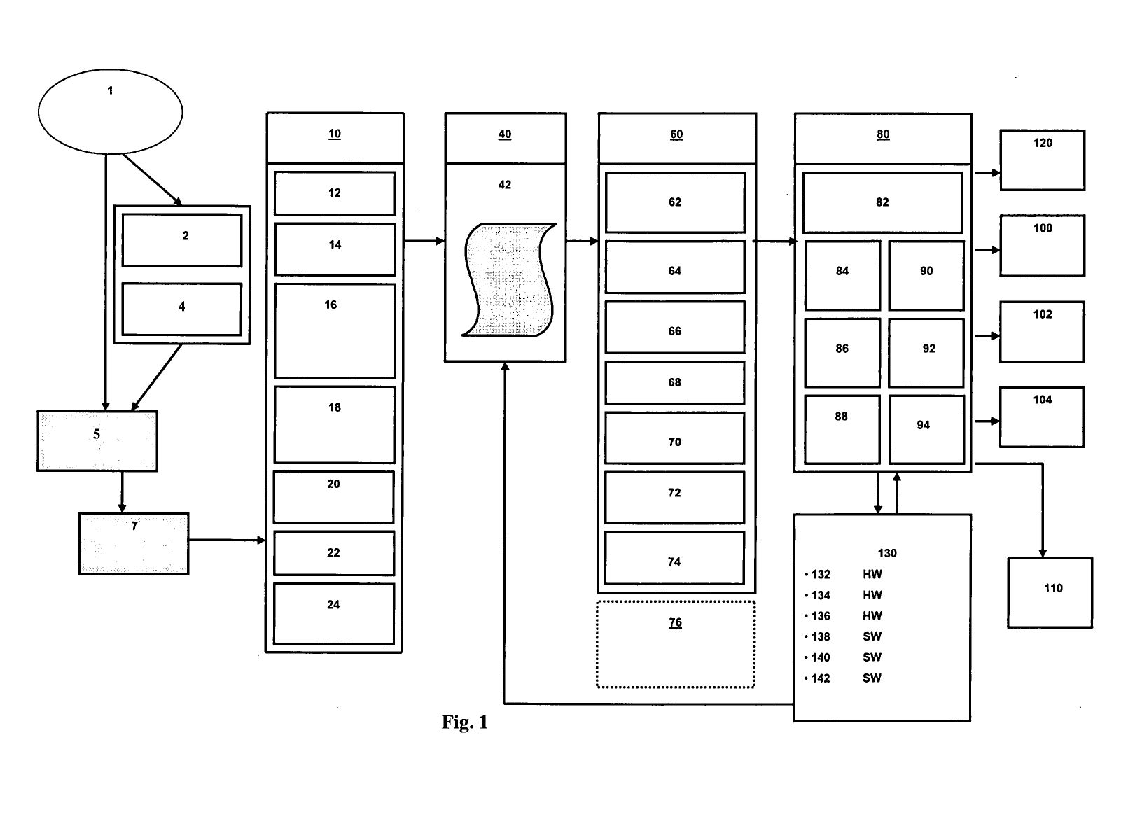

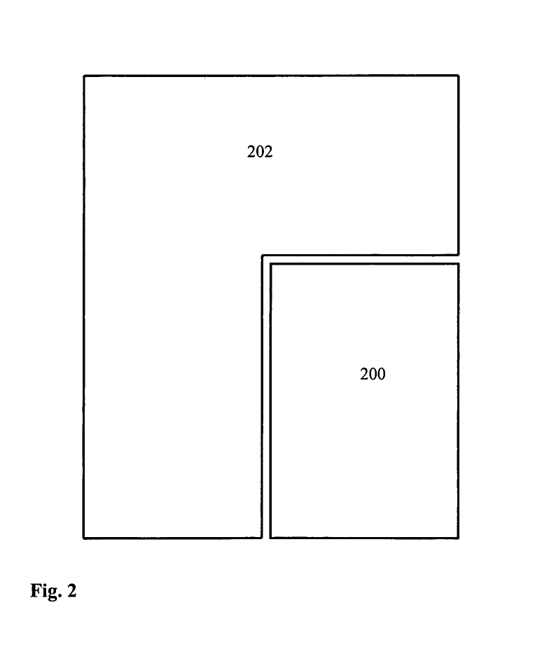

FIG. 1 shows the method as a first block diagram. The boxes 1, 5 and 7 are interfaces to the supplier of the IC to be tested. The supplier of an IC can provide a test by the method according to the invention at any stage of its development 1, i.e. as early as the time of the concept of the development as well as with the finished semiconductor IC. After a first summary test 2 and 4, which is optionally provided, it is possible to determine whether the desired checking of the IC is at all feasible 5. The summary test 2 and 4 comprises checking the test ability 2 and proposing the actual test strategy 4. The test strategy 4 includes decisions as to whether, for example, the safety-critical IC requires complete test coverage, also referred to as 100% functionality test, or whether only critical operating parameters or the range of normal continuous operation are or is tested. The concept of the semiconductor circuit 7, which is then present at some time as an IC, can be present as input data or specification 10 via different data. A conventional variant is the data sheet of the IC 12. Another specification 10 is a description of the use 14 of the IC. Starting from a general description of the use 14, an individual test for a certain type of IC can be provided 16 also on the basis of databases or other specific knowledge bases. A comprehensive frequency test in the case of each type of an amplifier could be mentioned as an embodiment. A further data source or specification 10 comprises the descriptions of the semiconductor circuit in a generally valid, machine-understandable language, such as VHDL 18. Other specifications are indications of particularly critical points in the design 20, of standard or particular test patterns 22, referred to among specialists as test patterns, or of a design or draft specification 24. From this specification 10 on the one hand and from the result of the code generator 80 or on the basis of the libraries 130 on the other hand, the test specification 42 is automatically written and made available in a manner comprehensible to the user as specification or as documentation 40 by means of deposited and automatically compilable text components. The test specification 42 can be output on computer, printer or data store. Instead of the test specification 42, and the specification 10 as a starting point, it is also possible to begin with the tester-independent test description in machine-understandable form 60. The tester-independent test description is advantageously present as one or more multidimensional matrices which can be influenced externally via a graphic, tabulated or editor interface. In the tester-independent test description 60, the data, control instructions and information, such as the test conditions 62, i.e. the number of pins, the relationship of the pins, the definitions of the supply voltages, the definitions of the voltages at the inputs of the IC to be tested, the limits 64, i.e. the data on the limits of the signals to be measured, the vectors 66, i.e. the list of test vectors, the test preparations 68, the sequencer commands and sequencer command sequences 70, the list of the scopes 72 of the test and the function test call-ups 74 of standard functions of the libraries 130 are present. The test-independent test description 60 is available to the code generator 80, which, with individual producers, generators, analyzers, parsers and linkers, with access to the libraries 130, generates the sequencer dependent on the test environment and capable of running either on one 100 or the other tester 102, 104. As an alternative, instead of executable sequencers, it is also possible to generate individual load board descriptions 110 or special tester-dependent specifications 120. The tester-independent test description 60 may be present as a machine-readable variant, either as a matrix or in a general tester language 76. The code generator 80 processes the stored information from the test matrix 60. The result of the processing is a specific sequencer for the selected tester 100, 102, 104. This sequencer is, as shown in FIG. 2, generated from the information of the general syntax 202 and the information of the syntax 200 dependent on the test environment. The code generator 80 employs further procedures and methods of the semiconductor circuits and of the relevant testers 100, 102, 104. These are stored in one of the libraries 130. The code generator 80 has a sequencer 82 which controls the conversion process. In the DC test generator 84, the DC tests are created from the information of the test description 60 independent of the test environment and from the libraries 130. In the AC test generator 86, the AC tests are created from the information of the test description 80 independent of the test environment and from the libraries 130. In the digital test generator 88, the digital tests are created from the information of the test descriptions 60 independent of the test environment and from the libraries 130. In the load board generator 92, the additional wiring for the load board is generated. With the rule checker 90, the syntax dependent on the test environment can be checked according to certain rules. With the optimizer 94, the syntax can be optimized with regard to certain requirements (e.g. test time, accuracy of the measured results, etc.).

The libraries 130 can be divided into libraries for tester resources 132, into libraries for load board description 134, into libraries for load board standard functions 136, tester standard functions 138, test standard functions 140 and IC-dependent typical standard functions 142. The following list is only by way of example. The designation HW or SW indicates whether the respective library 130 tends to include software (SW) or hardware (HW) descriptions. The tester resource library 132 may contain, for example, data on the number of possible channels, information about the time measuring means, information on the power supplies, information about the connection possibilities of the signals, information about the time behavior of the signals to be driven and information about the measuring means in the various testers 100, 102, 104 and test environments. The load board description library 134 may contain information about the wiring and the connection of the load boards. The library for the test environment standard function 138 contains control instructions, such as the superposition of the current and the voltage to be expected, information about the measurement of the supply voltage, information on carrying out the time measurement on one channel or on a plurality of channels, or the comprehensive testing of parameters of the semiconductor circuit. The code generator 80 employs the data of the test description 60 independent of the test environment in matrix form 76 or in a general tester language and runs through the matrix 76 with the sequencer 82 in various steps and generates a part of the syntax 200 according to FIG. 2, which is integrated in the general syntax 202. Below, a general tester language, a GTL, is shown by way of example:

| | |
|---|---|
| Pin_Assignment: | Pin1=CLK; |
| | Pin2=Uref1; |
| | Pin3=Reset; |
| | . |
| | . |
| | . |
| | Pin41=VCC1; |
| | Pin42=AGND; |
| | Pin43=GND; |
| | Pin44=U+; |
| Pin_Function: | Pin1=Input; |
| | Pin2=Input; |
| | Pin3=Input; |
| | . |
| | . |
| | . |
| | Pin41=Power; |
| | Pin42=PWD; |
| | Pin43=GND; |
| | Pin44=Output; |
| Settings: | VIL1=0.1V; |
| | VIL2=0.4V; |
| | VCC1=5.0V; |
| Limits: | LoLim1=0.1V; |
| | HiLim=1.2V; |
| MeasCond: | CurrentSource1 (Force=10mA, |
| | Measure=voltage, Range=2V, Clamp=5V); |
| Setup: | |
| { | |
| | Setup_Cond_No=1; |
| | Pin1=NC |
| | Pin2=NC |
| | Pin3=NC |
| | . |
| | . |
| | . |
| | Pin41=Power; |
| | Pin42=PWD; |
| | Pin43=GND; |
| | Setup_Cond_No=2; |
| | Pin1=VIH1 |
| | Pin2=VIH1 |
| | Pin3=VIH1 |
| | . |
| | . |
| | . |
| | Pin41=Power; |
| | Pin42=PWD; |
| | Pin43=GND; |
| | Set_Cond_No=3; |
| | Pin1=VIL1 |
| | Pin2=VIL1 |
| | Pin3=VIL1 |
| | . |
| | . |
| | . |
| | Pin41=Power; |
| | Pin42=PWD; |
| | Pin43=GND; |
| } | |
| Sequencer_Step: | |
| { | |
| | Test_No=1 |
| | Test_Name=Continuity; |
| | Pin1=VIL1 |
| | Pin2=VIL2 |
| | Pin3=VIL1 |
| | . |
| | . |
| | . |
| | Pin41=Power; |
| | Pin42=PWD; |
| | Pin43=GND; |
| | Pin44=Measure(Messwert_Test_No1, |
| | LoLim1, HiLim2, Pass-Bin, Fail-Bin); |
| } | |
| Sequencer: | |
| { | |
| | Do_Test_No1; |
| | Do_Test_No2; |
| | Delay_2ms; |
| | Do_Test_No3; |
| | Do_Test_No4; |
| | Make_Binning |
| } | |

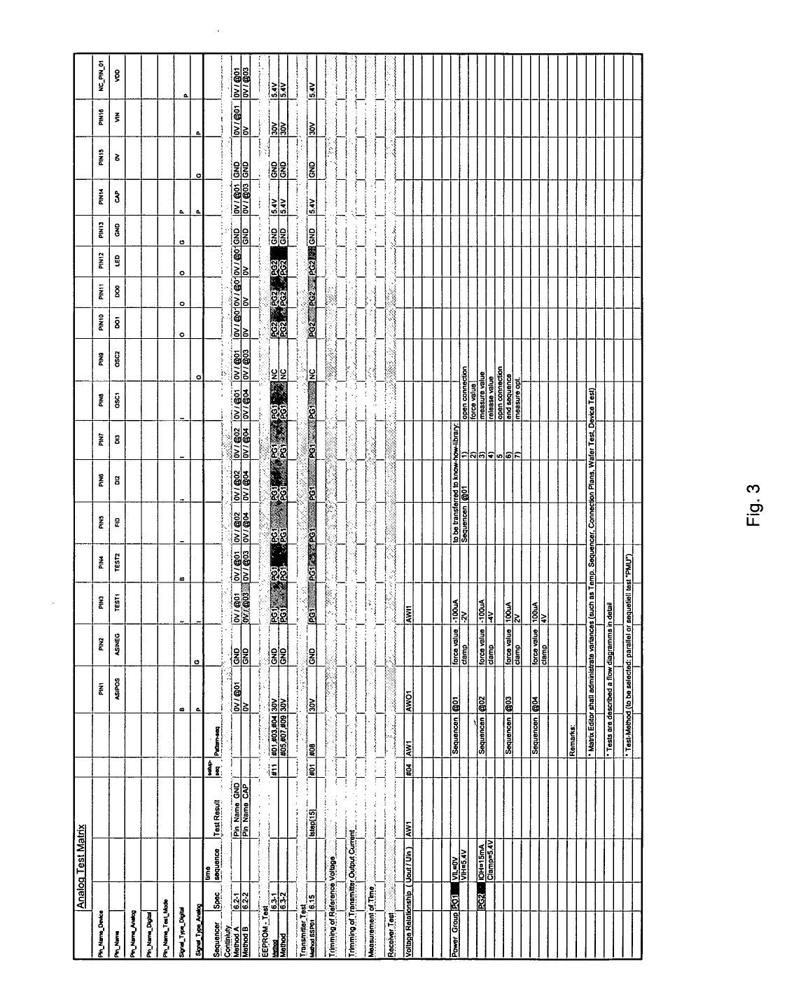

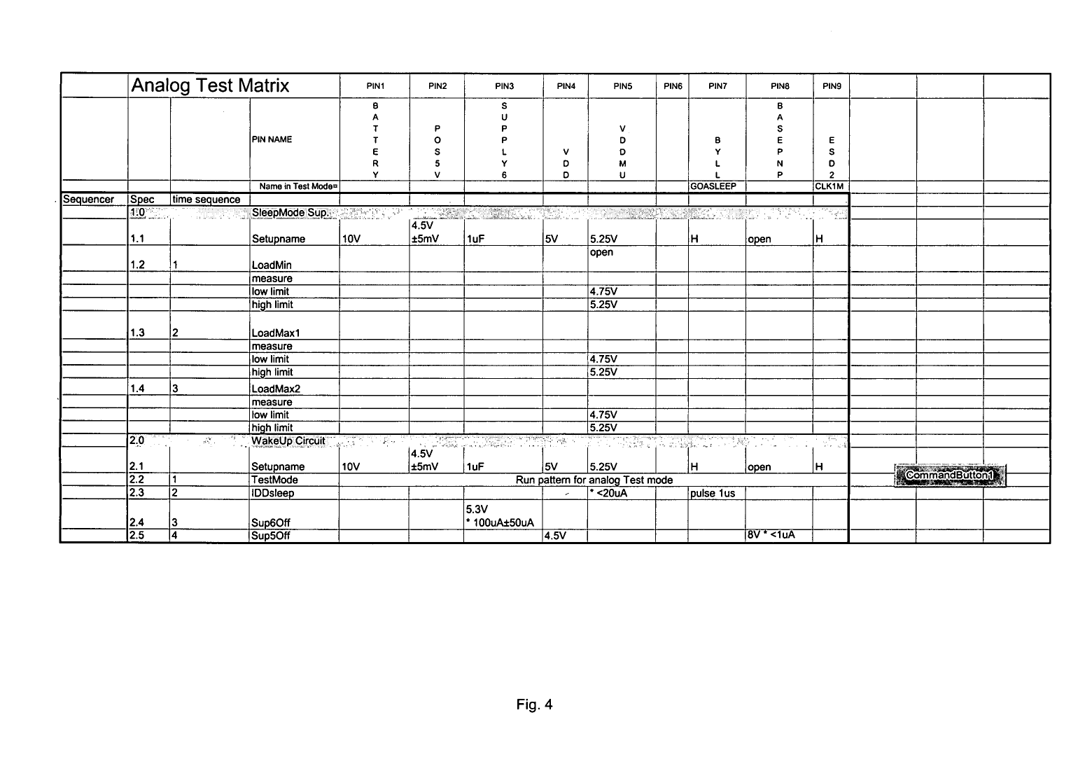

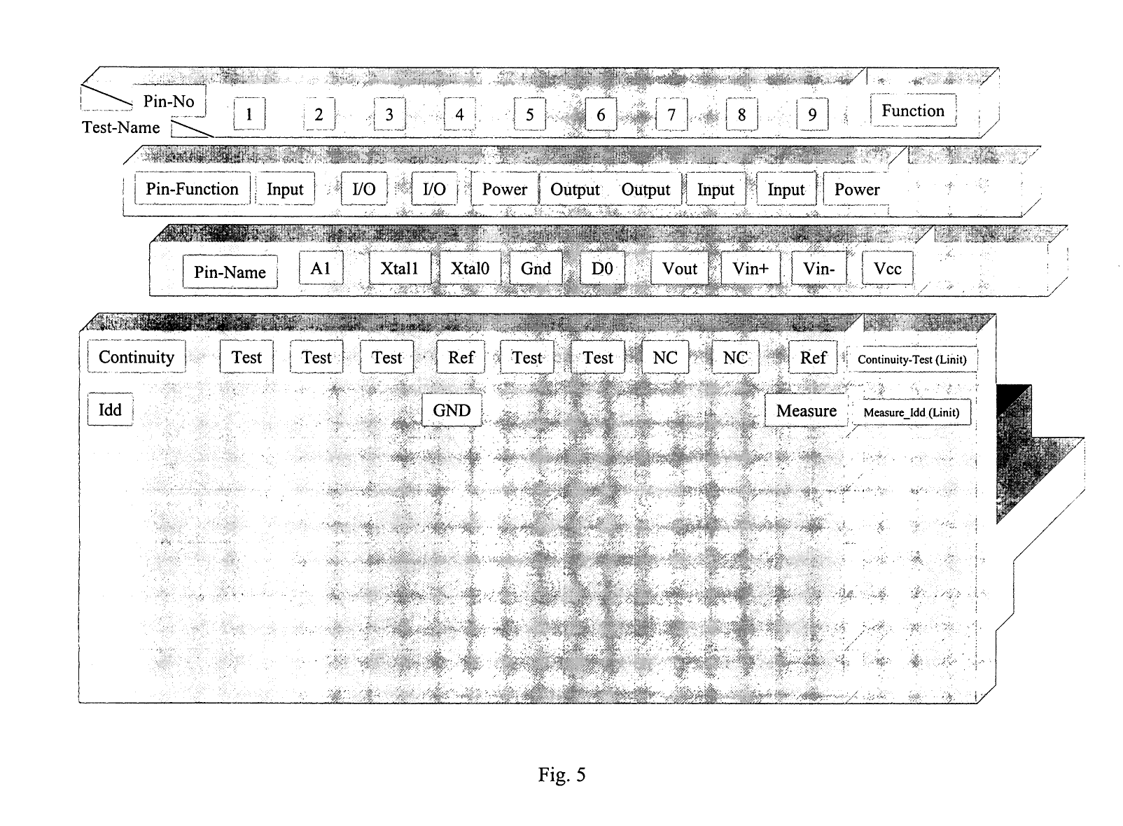

It is evident that such general tester-independent sequencers can span many lines and pages, the user quickly loses the overview, and only a user who systematically processes all sequencers can also design expedient tests. It may therefore be expedient in some situations to design the test matrix as in FIG. 3, FIG. 4 or FIG. 5, in order to maintain the overview of the important control groups and instructions at a glance. FIG. 3 and FIG. 4 represent two short, clear tests for two different ICs, one with 16 pins and one with 8 pins. They are written in a language which is familiar, simply on reading, to any electronics engineer and in particular to any person familiar with the IC test. It is therefore an associative language. FIG. 3 shows, in the middle of the matrix, comprehensive tests which are merely summarized under headings but are not further broken down, unless the test is further unfolded with the title “Time measurement” or with the title “Trimming of reference voltage” in order to see the planes and dimensions in the background. At the bottom of the matrix, comments can be included. All lines relating to pin names are unfolded. The individual lines contain information, such as, for example, pin number, pin name, pin direction, pin type, etc. The matrix shown in FIG. 3 is a test matrix which is reproduced as an input mask. It relates to a particular IC which has been designed by an IC developer as a specific ASIC with an analog and a digital portion which are related to one another. The example IC is equipped with 16 pins, and a name which simultaneously indicates a certain meaning of the pin to the user is assigned to each pin in the first lines. In further lines, a breakdown shows what a digital pin is and what an analog pin is. In addition, the respective line contains information on whether it is an input pin (I), an output pin (O), a bidirectional pin (O), a port pin (P) or a ground pin (G). Further codings which have other pin meanings are also possible, such as, for example, the breakdown of entire bus systems. The lines in the background give the titles of the individual tests, behind which, as illustrated, for example, in the case of the continuity test, the EEPROM test or the transmitter test in unfolded form, are further test methods which account for the entire test. Via the command “Sequencer” from the GTL, the time sequence of the tests is determined. From the lines, it is evident that analog-like test signals are to be applied to the analog and to the digital pins. As shown, for example, under the EEPROM test, the individual methods may refer to lower-lying matrices. The signals are applied in succession to pins, in particular staggered in terms of time, in the form of test patterns (pattern-seq). Selected voltage values, current values or sequences of simultaneously imposed currents at certain voltage values are applied to the individual pin according to the test. By means of the comments in the lower part of the matrices, particular sequences are determined, voltage change (Power_Group), which test sequences are to be deposited, preferably automatically, in a particular library and which special features are still present in the corresponding test matrix for the user.

In FIG. 4, the two tests with the titles “SleepModeSup.” and “WakeUpCircuit” are consecutively numbered as 1.0 and 2.0. The meaning of each individual test is classified by unfolding, the numbering being further subdivided. The user can adapt individual values in the tests. However, it is also sufficient for the code generator 80 if only the titles are specified. The matrix according to FIG. 5 nests the individual planes. The plane of the first depth is unfolded. The pins are classified with respect to the unfolding. The two tests listed are the test with the title “Continuity” and the test with the title “Idd”. Both are special tests which originate from the inventors of the method. They are tests which, in the case of the continuity test, constitute a first test for ICs, by means of which it is ensured whether all pins are connected to the tester head. The test “Idd” measures the current flow between different pins.

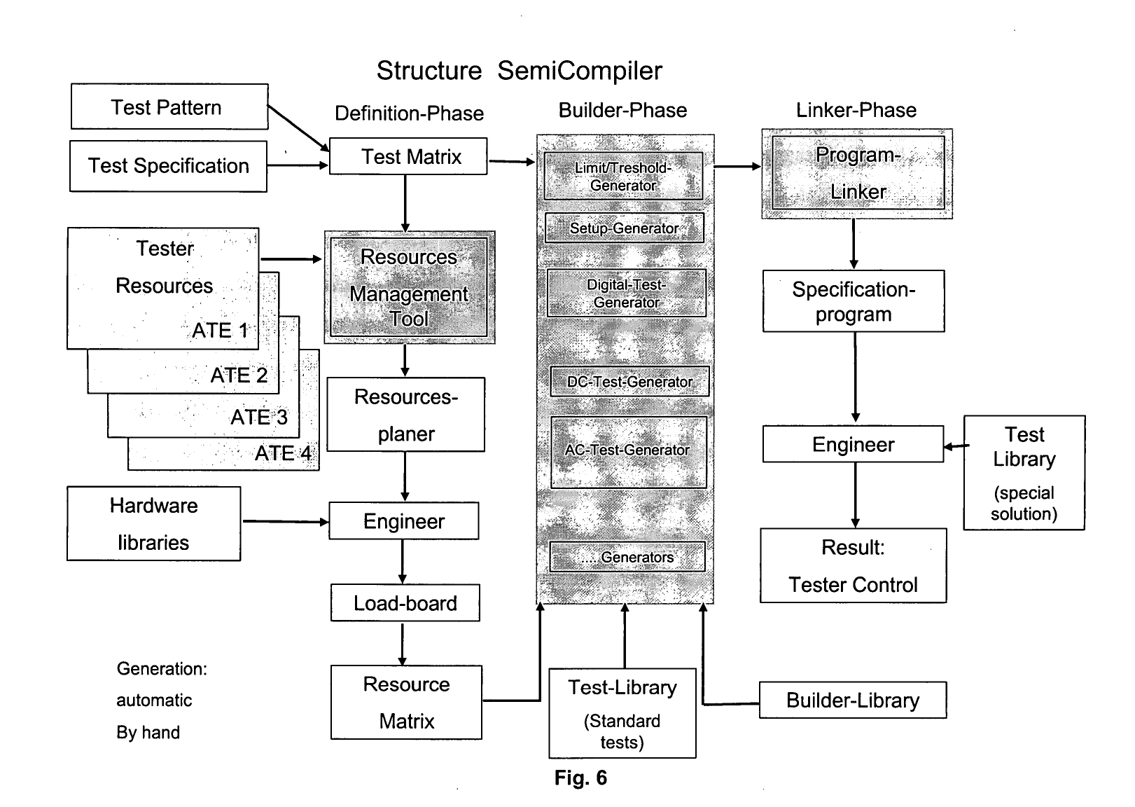

In the sequence diagram according to FIG. 6, the method according to the invention is shown with some modifications compared with the embodiment according to FIG. 1. The underlying blocks comprise the automated part of the method. In the builder phase, the individual generators are triggered and the data are extracted from the test matrix. When all builder stages have been passed through, the linker is started in the linker phase and creates the final syntax by linking. The builder employs the various libraries, which a user, in this case an engineer, can influence. The resource management tool checks beforehand whether generation and combination of the generated syntax parts into an overall syntax are at all possible. For this purpose, the resource management tool knows the compilations and possibilities of the testers and test environments.

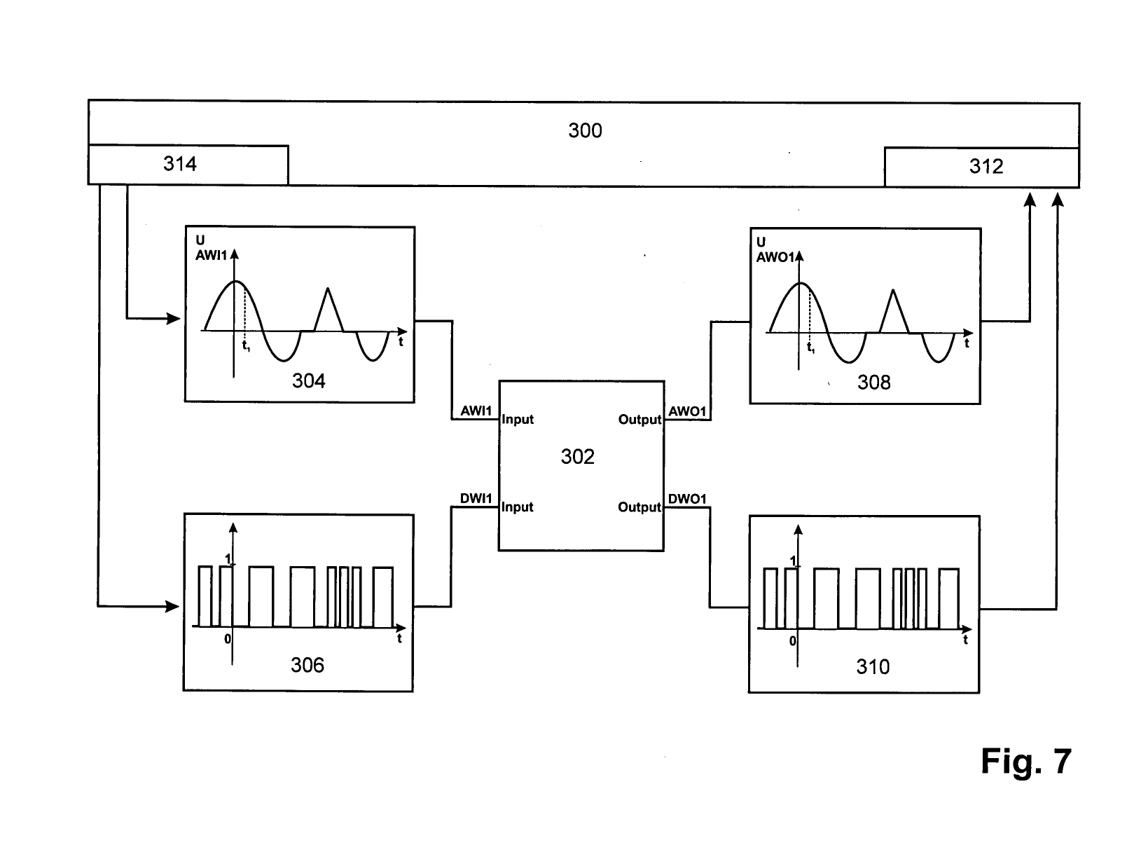

FIG. 7 schematically shows a certain test environment 300 with a device under test 302, a mixed-signal IC. On the generation side 314, a separate analog wave 304 is generated per input pin AWI1, which requires an analog test signal, while at the same time a digital wave 306 is generated for a digital in DWI1. The output signals AWO1 for the analog output pin and DWO1 for the digital output pin are transmitted via a recording unit for an analog signal 308 and for a digital signal 310 to a common evaluation unit 312 in the test environment 300, which evaluation unit can implement the specifications for such tests, such as the ratio of the gain, the phase position and the lag and the time difference from the individual signals recorded. The gain is determined, for example, by relating the output voltage signal to the input voltage signal. Finally, the test data are compared with limits in order to carry out the so-called binning, a classification as to whether a mixed-signal IC is good or bad. If a limit is significantly exceeded in a test in the test sequence, the test program responds, depending on the setting, by terminating the test, rejects the mixed-signal IC and carries out the tests for the next IC.

Although only individual embodiments of the method according to the invention are described, it is self-evident that, instead of a test matrix, it is also possible, as a further variant of the method, to start from a general language GTL as a starting point for the code generator; it is also self-evident that the matrix can trigger the code generator for a sequence, instead of the code generator controlling the matrix; and, of course, the libraries can be subdivided as desired. All these embodiments are likewise part of the invention described.

1. A method which generates an IC tester control consisting of numerous test instructions for a plurality of specific test environments, which can generate and measure analog and digital signals for an IC, in particular a mixed-signal IC,
wherein
the method obtains data and control instructions from multidimensional test matrices independent of the test environment, such as matrix-like databases or libraries,
the data and control instructions independent of the test environment are converted by means of a code generator into a syntax which is dependent on the test environment and which can be integrated into a general syntax dependent on the test environment, so that the syntax dependent on the test environment and the general syntax dependent on the test environment together form a complete control, comprising analog and digital signals, for one of the specific test environments.

2. The method as claimed in claim 1, wherein, during its conversion phase, the code generator employs a library group in which are integrated various libraries which contain at least partial information with respect to
a) the test environment,
b) the syntax dependent on the test environment,
c) the test environment resources,
d) the sequence of test methods,
e) the standard functions of the test environment,
f) the load board structure,
g) the standard functions dependent on the load board and
h) the code generator optimization.

3. The method as claimed in claim 1, wherein a multidimensional test matrix has,
in a first dimension, data on the number and arrangement of pins of the IC,
in a further dimension, data on the meaning, the name and the signal flow direction of the pins of the IC,
in a further dimension, sequences of test instructions,
in a further dimension, test instruction headings which summarize individual test instructions,
in one dimension, specifies general test conditions,
in one dimension, specifies the start conditions for a test,
in one dimension, specifies test patterns,
in one dimension, specifies functional descriptions of the tests,
in one dimension, specifies switching values,
in one dimension, specifies conditions for quality sorting of ICs.

4. The method as claimed in claim 1, wherein the code generator comprises at least one of the following components;
a DC test generator which reads out and converts the data and control instructions from matrices, which generate DC voltage values for an IC in the test environment,
an AC test generator which reads out and converts the data and control instructions from matrices, which generate AC voltage values or signal curves for an IC in the test environment,
a digital test generator which reads out and converts the data and control instructions from matrices, which generate digital voltage values for an IC in the test environment,
a load board generator which reads out and converts the data and control instructions from matrices, which refer to the resources and requirements with respect to the load conditions of the load boards of the test environment,
a test rule verifier which checks whether the data and control instructions of the syntax dependent on the test environment can be executed in the test environment,
and the code generator runs through a multistage method
in the first stage of which the data and control instructions of a matrix are made available to the code generator as source information,
in the second stage of which the source information is processed in succession, in each case by one of the components, the last component being the test rule verifier,
and, in the third stage of which, the converted data and control instructions are modified by means of an optimizer with respect to resource utilization of the test environment, test speed, test sequences or waiting and idle times between
individual data and control instructions.

5. The method as claimed in claim 1, wherein a processible data sheet of the IC serves as the origin for the matrices independent of the test environment, on the basis of which data sheet automated test description documentations are generated from the matrices and name, in a generally legible manner, the scope, the type, the duration and the type of the data and control instructions.

6. The method as claimed in claim 1, wherein signals which are analog and/or digital are read in from the test environment, preferably with a time lag after superposition of signals of the control, in order to be evaluated via mixed-signal test methods, such as, for example, a method for the gain or gains, the voltage ratios, the frequency responses, the phase positions, the wave shapes, the harmonics and/or the transit-time behavior.

7. A method which generates an IC tester control, consisting of numerous test instructions, for a plurality of specific test environments, which can generate and measure analog and digital signals for an IC, in particular a mixed-signal IC,
wherein
the individual specific test environments differ from one another in their structure and/or their syntax,
the method obtains data and control instructions from multidimensional test matrices independent of the test environment, such as matrix-like databases or libraries,
the data and control instructions independent of the tester environment are converted by means of a code generator into a syntax which is dependent on the test environment and which can be integrated into a general syntax dependent on the test environment, so that the syntax dependent on the test environment and the general syntax dependent on the test environment together form a complete control, comprising analog and digital signals, for one of the specific test environments.

8. The method as claimed in claim 7, wherein, in the multidimensional test matrices, it is possible to list test methods which enable both digital and analog signals of the control of the test environment to occur synchronously.

9. The method as claimed in claim 8, wherein a multidimensional test matrix has,
in a first dimension, data on the number and arrangement of pins of the IC,
in a further dimension, data on the meaning, the name and the signal flow direction of the pins of the IC,
in a further dimension, sequences of test instructions,
in a further dimension, test instruction headings which summarize individual test instructions,
in one dimension, specifies general test conditions,
in one dimension, specifies the start conditions for a test,
in one dimension, specifies test patterns,
in one dimension, specifies functional descriptions of the tests,
in one dimension, specifies switching values,
in one dimension, specifies conditions for quality sorting of ICs.

10. The method as claimed in claim 9, wherein, during its conversion phase, the code generator employs a library group in which are integrated various libraries which contain at least partial information with respect to
a) the test environment,
b) the syntax dependent on the test environment,
c) the test environment resources,
d) the sequence of test methods,
e) the standard functions of the test environment,
f) the load board structure,
g) the standard functions dependent on the load board and
h) the code generator optimization.

11. The method as claimed in claim 7, wherein furthermore the code generator comprises at least one of the following components;
a DC test generator which reads out and converts the data and control instructions from matrices, which generate DC voltage values for an IC in the test environment,
an AC test generator which reads out and converts the data and control instructions from matrices, which generate AC voltage values or signal curves for an IC in the test environment,
a digital test generator which reads out and converts the data and control instructions from matrices, which generate digital voltage values for an IC in the test environment,
a load board generator which reads out and converts the data and control instructions from matrices, which refer to the resources and requirements with respect to the load conditions of the load boards of the test environment,
a test rule verifier which checks whether the data and control instructions of the syntax dependent on the test environment can be executed in the test environment,
and the code generator runs through a multistage method
in the first stage of which the data and control instructions of a matrix are made available to the code generator as source information,
in the second stage of which the source information is processed in succession, in each case by one of the components, the last component being the test rule verifier,
and, in the third stage of which, the converted data and control instructions are modified by means of an optimizer with respect to resource utilization of the test environment, test speed, test sequences or waiting and idle times between individual data and control instructions.

12. The method as claimed in claim 10, wherein a processible data sheet of the IC serves as the origin for the matrices independent of the test environment, on the basis of which data sheet automated test description documentations are generated from the matrices and name, in a generally legible manner, the scope, the type, the duration and the type of the data and control instructions.

13. The method as claimed in claim 8, wherein signals which are analog and/or digital are read in from the test environment, preferably with a time lag after superposition of signals of the control, in order to be evaluated via mixed-signal test methods, such as, for example, a method for the gain or gains, the voltage ratios, the frequency responses, the phase positions, the wave shapes, the harmonics and/or the transit-time behavior.

14. A method which generates an IC tester control, consisting of numerous test instructions, for a plurality of specific test environments, which can generate and measure analog and digital signals for an IC, in particular a mixed-signal IC,
wherein
the method obtains data and control instructions from multidimensional test matrices independent of the test environment, such as matrix-like databases or libraries,
the data and control instructions independent of the test environment are converted by means of a code generator into a syntax which is dependent on the test environment and which can be integrated into a general syntax dependent on the test environment, so that the syntax dependent on the test environment and the general syntax dependent on the test environment together form a complete control, comprising analog and digital signals, for one of the specific test environments, and
test methods which allow both digital and analog signals of the control of the test environment to occur synchronously can be listed in the multidimensional test matrices.

15. The method as claimed in claim 14, wherein, during its conversion phase, the code generator employs a library group in which are integrated various libraries which contain at least partial information with respect to
a) the test environment,
b) the syntax dependent on the test environment,
c) the test environment resources,
d) the sequence of test methods,
e) the standard functions of the test environment,
f) the load board structure,
g) the standard functions dependent on the load board and
h) the code generator optimization.

16. The method as claimed in claim 15, wherein signals which are analog and/or digital are read in from the test environment, preferably with a time lag after superposition of signals of the control, in order to be evaluated via mixed-signal test methods, such as, for example, a method for the gain or gains, the voltage ratios, the frequency responses, the phase positions, the wave shapes, the harmonics and/or the transit-time behavior.

17. The method as claimed in claim 16, wherein a multidimensional test matrix has,
in a first dimension, data on the number and arrangement of pins of the IC,
in a further dimension, data on the meaning, the name and the signal flow direction of the pins of the IC,
in a further dimension, sequences of test instructions,
in a further dimension, test instruction headings which summarize individual test instructions,
in one dimension, specifies general test conditions,
in one dimension, specifies the start conditions for a test,
in one dimension, specifies test patterns,
in one dimension, specifies functional descriptions of the tests,
in one dimension, specifies switching values,
in one dimension, specifies conditions for quality sorting of ICs.

18. The method as claimed in claim 17, wherein the code generator (80) comprises at least one of the following components;
a DC test generator which reads out and converts the data and control instructions from matrices, which generate DC voltage values for an IC in the test environment,
an AC test generator which reads out and converts the data and control instructions from matrices, which generate AC voltage values or signal curves for an IC in the test environment,
a digital test generator which reads out and converts the data and control instructions from matrices, which generate digital voltage values for an IC in the test environment,
a load board generator which reads out and converts the data and control instructions from matrices, which refer to the resources and requirements with respect to the load conditions of the load boards of the test environment,
a test rule verifier which checks whether the data and control instructions of the syntax dependent on the test environment can be executed in the test environment,
and the code generator runs through a multistage method
in the first stage of which the data and control instructions of a matrix are made available to the code generator as source information,
in the second stage of which the source information is processed in succession, in each case by one of the components, the last component being the test rule verifier,
and, in the third stage of which, the converted data and control instructions are modified by means of an optimizer with respect to resource utilization of a test environment, test speed, test sequences or waiting and idle times between individual data and control instructions.

19. The method as claimed in claim 18, wherein a processible data sheet of the IC serves as the origin for the matrices independent of the test environment, on the basis of which data sheet automated test description documentations are generated from the matrices and name, in a generally legible manner, the scope, the type, the duration and the type of the data and control instructions.

20. The method as claimed in claim 19, wherein the individual specific test environments differ from one another in their structure and/or their syntax.

21. A data medium which can be processed by a microprocessor-controlled computer on which a method as claimed in claim 1 is physically incorporated.

22. A microprocessor-controlled computer having a central operating system which is electrically connected to at least one test environment on which a method as claimed in claim 1 runs.
